(19) United States
(12) Patent Application Publication
(10) Pub. No.: US 2026/0112978 A1
(43) Pub. Date: Apr. 23, 2026

(54) POWER MODULE FOR VEHICLE AND MANUFACTURING METHOD THEREOF

(71) Applicants: HYUNDAI MOTOR COMPANY, Seoul (KR); KIA CORPORATION, Seoul (KR)

(72) Inventors: Sang Hyun Lee, Hwaseong-si (KR); Su Gil Kim, Hwaseong-si (KR)

(73) Assignees: HYUNDAI MOTOR COMPANY, Seoul (KR); KIA CORPORATION, Seoul (KR)

(21) Appl. No.: 19/201,874

(22) Filed: May 7, 2025

(30) Foreign Application Priority Data
Oct. 18, 2024 (KR) 10-2024-0143200

(51) Int. Cl. H02M 7/00; B60L 15/00; H05K 1/02; H05K 1/14; H05K 3/30

(52) U.S. Cl. CPC H02M 7/003; B60L 15/007; H05K 1/0203; H05K 1/144; H05K 3/305; B60L 2210/40; H05K 2201/10053; H05K 2201/10522; H05K 2203/1131; H05K 2203/1305

(57) ABSTRACT

A power module for a vehicle is provided. The power module includes a circuit board, a switching component disposed on the circuit board, and an adhesive member bonded to at least one of the circuit board or the switching component, wherein a boundary of an edge portion, thinner than a center portion of the adhesive member, is slanted with respect to an adhesion surface of the center portion of the adhesive member.

### CROSS-REFERENCE TO RELATED APPLICATION(S)

This application claims benefit of priority to Korean Patent Application No. 10-2024-0143200 filed on Oct. 18, 2024, in the Korean Intellectual Property Office, the disclosure of which is incorporated herein by reference in its entirety.

### TECHNICAL FIELD

The present disclosure relates to a power module for a vehicle and a method for manufacturing a power module for a vehicle.

### BACKGROUND

Eco-friendly vehicles may include hybrid vehicles (HEVs), plug-in hybrid vehicles (HEVs), electric vehicles (EVs), fuel cell electric vehicles (FCEVs), or the like. A power module of an eco-friendly vehicle receives DC current from a high-voltage battery, converts the received DC current into AC current, supplies the AC current to a motor, and controls the torque and a rotation speed of the motor by adjusting the magnitude and phase of the AC current.

### SUMMARY

Power modules for vehicles may be used in harsh environments (e.g., high current influence, high heat generation influence, high variability in vehicle operation, high variability in the vehicle external environment, and the like) and may cause heat generation. Harsh environments and/or heat generation may impact (e.g., cause higher) bonding reliability of switching components and/or circuit boards of power modules for vehicles. A power module for a vehicle and a method for manufacturing a power module for a vehicle according to an example embodiment of the present disclosure may improve the bonding reliability of switching components and/or circuit boards of a power module for a vehicle.

According to the present disclosure, a power module for a vehicle includes a circuit board, a switching component disposed on the circuit board, and an adhesive member bonded to at least one of the circuit board and the switching component, wherein a boundary of an edge portion, thinner than a center portion of the adhesive member, is slanted with respect to an adhesion surface of the center portion of the adhesive member.

The boundary of the edge portion, thinner than the center portion of the adhesive member, may be more curved than the adhesion surface of the center portion of the adhesive member.

The adhesive member may include a metal material and may be configured to be bonded to at least one of the circuit board and/or the switching component by sintering.

The power module may further include a spacer disposed on the switching component, wherein the circuit board may include a first circuit board and a second circuit board, the switching component may be disposed between the first circuit board and the spacer, and the spacer may be disposed between the second circuit board and the switching component.

The adhesive member may include a first adhesive member bonded between the first circuit board and the switching component, a second adhesive member bonded between the switching component and the spacer, and a third adhesive member bonded between the spacer and the second circuit board, and, in at least one of the first adhesive member, the second adhesive member and the third adhesive member, a boundary of an edge portion thinner than a center portion is slanted with respect to an adhesion surface of the center portion.

The power module may further include an encapsulant encapsulating the switching component and the spacer and directly contacting the boundary of the edge portion of at least one of the first adhesive member, the second adhesive member and the third adhesive member.

The adhesive member may include a first adhesive member bonded to the switching component, and an edge portion of the first adhesive member may not overlap the switching component in a direction in which a center of the first adhesive member and a center of the switching component face each other.

A maximum width of the edge portion of the first adhesive member not overlapping the switching component may be greater than 0 μm and less than or equal to 50 μm.

The adhesive member may include a first adhesive member bonded to the switching component, the switching component may include a plurality of active regions and a gate runner region between the plurality of active regions, and the first adhesive member may be bonded to each of the plurality of active regions and is spaced apart from the gate runner region.

Each of a plurality of corners of an adhesion surface of the first adhesive member may have a more chamfered shape than that of each of a plurality of corners of the plurality of active regions.

A boundary in the first adhesive member facing the gate runner region may be slanted with respect to an adhesion surface of the first adhesive member bonded to the plurality of active regions.

The adhesive member may include a first adhesive member bonded to one surface of the switching component, and a second adhesive member bonded to the other surface of the switching component, the switching component may include a plurality of switching components having different thicknesses, and a portion and another portion of the second adhesive member may be spaced apart from each other and respectively bonded to the plurality of switching components.

According to another aspect of the present disclosure, a method for manufacturing a power module for a vehicle includes an operation of applying an adhesive material to at least one of a circuit board and a switching component in a jetting manner, and an operation of sintering the applied adhesive material to form an adhesive member bonded to at least one of the circuit board and the switching component.

The circuit board may include a first circuit board and a second circuit board. The operation of forming the adhesive member may include forming a first adhesive member bonded between the first circuit board and the switching component, and may include forming a second adhesive member bonded between the switching component and a spacer. The applying operation may include applying a first adhesive material, a base of the first adhesive member, in a jetting manner, and may include applying a second adhesive material, a base of the second adhesive member, in a jetting manner.

The applying operation may include curing the applied first adhesive material before sintering and curing the applied second adhesive material before sintering.

The applying operation may include applying a portion of the first adhesive material along a 1 -1 application path of a predetermined first application region of at least one of the circuit board and the switching component in a jetting manner, applying another portion of the first adhesive material along a 1-2 application path of the predetermined first application region in a jetting manner, applying a portion of the second adhesive material along a 2-1 application path of a predetermined second application region of at least one of the switching component and the spacer, and applying another portion of the second adhesive material along a 2 -2 application path of the predetermined second application region in a jetting manner. At least a portion of the 1-2 application path may not overlap the 1 -1 application path within the predetermined first application region, and at least a portion of the 2 -2 application path may not overlap the 2-1 application path within the predetermined second application region.

The applying operation may include applying a portion of the adhesive material along a first application path of a predetermined application region of at least one of the circuit board and the switching component in a jetting manner, and applying another portion of the adhesive material along a second application path of the predetermined application region in a jetting manner. Within the predetermined application region, at least a portion of the second application path may not overlap the first application path.

The applying operation may include applying an adhesive material to a predetermined application region of at least one of the circuit board and the switching component in a jetting manner. The switching component may have a plurality of active regions and a gate runner region between the plurality of active regions, and the predetermined application region may overlap each of the plurality of active regions and does not overlap the gate runner region.

The applying operation may include applying an adhesive material to a predetermined application region of at least one of circuit board and the switching component in a jetting manner, wherein the switching component may include a plurality of switching components having different thicknesses, and the predetermined application region may overlap each of the plurality of switching components and may not overlap a region between the plurality of switching components.

### BRIEF DESCRIPTION OF DRAWINGS

The above and other aspects, features, and improvements of the present disclosure will be understood from the following detailed description, taken in conjunction with the accompanying drawings.

FIG. 1A is a side view illustrating a power module for a vehicle according to an embodiment of the present disclosure.

FIG. 1B is a side view illustrating a single circuit board structure of a power module for a vehicle according to an embodiment of the present disclosure.

FIG. 1C is a side view illustrating a thickness difference between a plurality of switching components of a power module for a vehicle according to an embodiment of the present disclosure.

FIG. 1D is a plan view illustrating various shapes of a plurality of switching components of a power module for a vehicle according to an embodiment of the present disclosure.

FIG. 2A is a plan view illustrating a switching component of a power module for a vehicle according to an embodiment of the present disclosure.

FIG. 2B is a plan view illustrating a structure in which an adhesive material is applied to a portion of a switching component of a power module for a vehicle according to an embodiment of the present disclosure.

FIG. 3A is a side view illustrating applying an adhesive material of a power module for a vehicle in a jetting manner according to an embodiment of the present disclosure.

FIG. 3B is a side view illustrating applying an adhesive material to a portion of a component of a power module for a vehicle according to an embodiment of the present disclosure.

FIG. 4 is a side view illustrating a shape of an adhesive member of a power module for a vehicle according to an embodiment of the present disclosure.

FIG. 5A is a perspective view illustrating an applied adhesive material of a power module for a vehicle before being flattened according to an embodiment of the present disclosure.

FIG. 5B is a perspective view illustrating a flattened adhesive material of a power module for a vehicle after being applied according to an embodiment of the present disclosure.

FIG. 6A is a plan view illustrating applying a portion of an adhesive material along a first application path in a jetting manner in a method of a manufacturing a power module fora vehicle according to an embodiment of the present disclosure.

FIG. 6B is a plan view illustrating applying another portion of an adhesive material along a second application path in a jetting manner in a method of a manufacturing a power module for a vehicle according to an embodiment of the present disclosure.

FIG. 7A is a flowchart illustrating a method for manufacturing a power module for a vehicle according to an embodiment of the present disclosure.

FIG. 7B is a flowchart illustrating a change in a curing time of a method for manufacturing a power module for a vehicle according to an embodiment of the present disclosure.

FIG. 7C is a flowchart illustrating a preform process of an adhesive material in a method for manufacturing a power module for a vehicle according to an embodiment of the present disclosure.

### DETAILED DESCRIPTION

While the present disclosure may be modified in various ways and take on various alternative forms, specific embodiments thereof are shown in the drawings and described in detail below. However, it should be understood that the present disclosure is not limited to the forms disclosed, but on the contrary, the present disclosure covers (e.g., all) modifications, equivalents, and alternatives falling within the spirit and scope of the present disclosure.

Although the terms “first,” “second,” and/or the like may be used herein to describe various elements, these elements should not be limited by these terms. These terms are used to distinguish one element from another. For example, a first element could be termed a second element, and a second element could similarly be termed a first element without departing from the scope of the present disclosure. As used herein, the term “and/or” includes (e.g., any and all) combinations of one or more of the associated listed items.

The terms used herein to describe embodiments of the present disclosure is not intended to limit the scope of the present disclosure. The articles “a,” and “an” are singular in that they have a single referent, however the use of the singular form in the present document should not preclude the presence of more than one referent. In other words, elements of the present disclosure referred to in the singular may be one or more element, unless the context indicates otherwise. The terms “comprise,” “comprising,” “include,” and/or “including,” when used herein, disclose the presence of stated features, numbers, steps, operations, elements, and/or components but do not preclude the presence or addition of one or more other features, numbers, steps, operations, elements, components, and/or groups thereof.

Unless defined in a different way, the terms used herein including technical and scientific terms have the same meanings as understood by those skilled in the art to which the present disclosure pertains.

In this specification, vehicles refer to a variety of vehicles that move transported objects, such as people, animals, or goods, from a starting point to a destination. These vehicles are not limited to vehicles that drive on roads or tracks.

Hereinafter, embodiments of the present disclosure will be described with reference to the accompanying drawings.

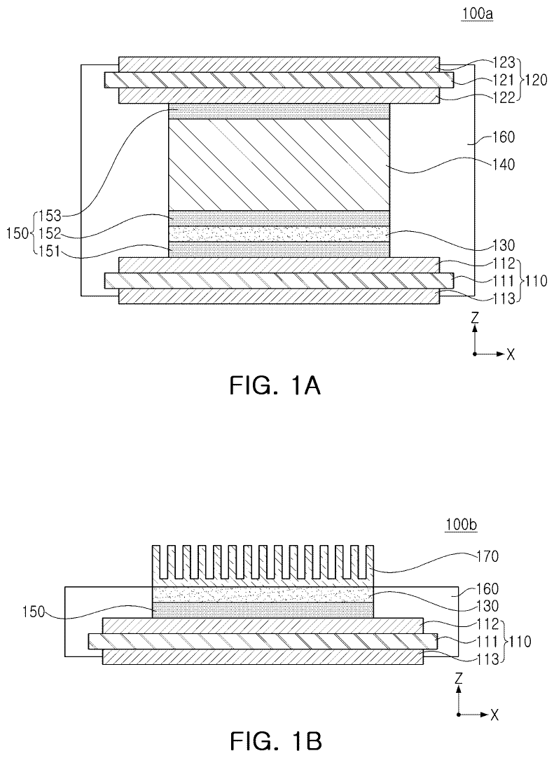

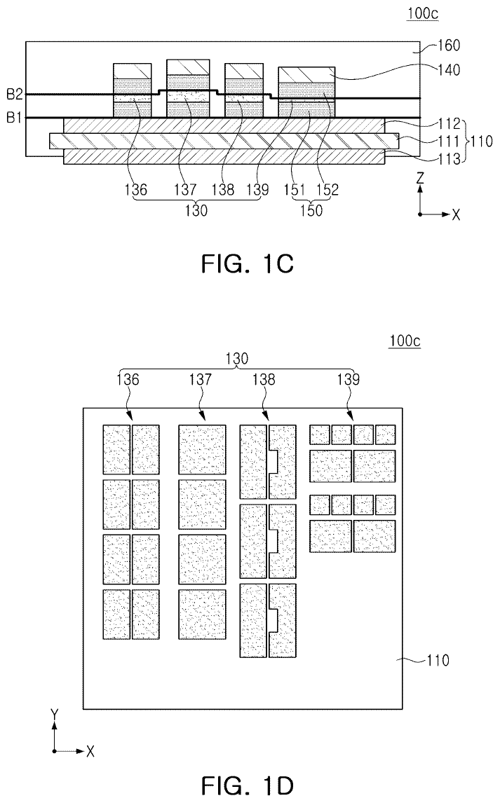

FIGS. 1A, 1B, and 1C are side views illustrating a power module for a vehicle according to an embodiment of the present disclosure. Referring to FIGS. 1A to 1C, power modules 100a, 100b, and 100c for a vehicle according to an embodiment of the present disclosure may include a circuit board (e.g., a first circuit board 110 and/or a second circuit board 120), a switching component 130, and an adhesive member 150.

The circuit board may include the first circuit board 110 and/or the second circuit board 120, the first circuit board 110 may include an insulating layer 111, a first metal layer 112, and a second metal layer 113, and the second circuit board 120 may include an insulating layer 121, a first metal layer 122, and a second metal layer 123. For example, the first circuit board 110 and/or the second circuit board 120 may be implemented as an active metal brazed (AMB) substrate or a direct bonded copper (DBC) substrate, the insulating layers 111 and 121 may be implemented as ceramic layers, the first metal layers 112 and 122 may be implemented as copper layers, and the second metal layers 113 and 123 may be implemented as copper layers, but are not limited thereto.

Portions of the insulating layers 111 and 121 may overlap the first metal layers 112 and 122 in a vertical direction (e.g., a Z-direction), and other portions of the insulating layers 111 and 121 may not overlap the first metal layers 112 and 122 in the vertical direction (e.g., the Z-direction). For example, the first metal layers before patterning may be formed to overlap the (e.g., entire) region of the insulating layers 111 and 121, portions of the first metal layers before patterning may be removed by a patterning method (e.g., a photolithography method), and the first metal layers 112 and 122 after patterning may include a plurality of patterns, and the plurality of patterns may provide a plurality of electrical connection paths for the switching component 130.

For example, the second metal layers 113 and 123 may dissipate heat generated by the switching component 130 and the first metal layers 112 and 122 to the outside of the power modules 100a, 100b, and 100c and may be electrically separated from the first metal layers 112 and 122 by the insulating layers 111 and 121. Alternatively, the second metal layers 113 and 123 may provide a ground for the switching component 130 and may be electrically connected to some patterns of the first metal layers 112 and 122 through conductive vias of the insulating layers 111 and 121. A cooling channel (not shown) for cooling the power modules 100a, 100b, and 100c may be in contact with a lower surface of the second metal layer 113 or an upper surface of the second metal layer 123.

The switching component 130 may be disposed on a circuit board (e.g., the first circuit board 110 and/or the second circuit board 120). For example, the switching component 130 may include a semiconductor device, such as an insulated gate bipolar transistor (IGBT) or a metal oxide semiconductor field effect transistor (MOSFET). The switching component 130 may further include a diode and may be implemented as at least one of an integrated circuit, a chip, and/or a die. The switching of the switching component 130 may refer to switching between an ON state and an OFF state of the semiconductor device.

The switching component 130 may receive a control signal from an external source (e.g., a motor controller) of the power modules 100a, 100b, and 100c through a signal lead (not shown) and may switch the ON/OFF state of the semiconductor device according to the control signal. According to the switching of the switching component 130, the switching component 130 may invert a direct current (DC) input from an external source (e.g., a battery) through a DC lead frame (not shown) into an alternating current (AC) and output the AC externally (e.g., to a motor) through an AC lead frame. Therefore, the switching component 130 may be at least a portion of an inverter circuit.

The adhesive member 150 may be bonded to at least one of the circuit board (e.g., the first circuit board 110 and/or the second circuit board 120) and the switching component 130. For example, the adhesive member 150 may include a metal material (e.g., silver (Ag) nano gel mixed with a solvent) and may be configured to be bonded to at least one of the circuit board (e.g., the first circuit board 110 and/or the second circuit board 120) and the switching component 130 by sintering. The sintering may be implemented by a sintering process.

Compared to other (e.g., general) components, the switching component 130 of the power modules 100a, 100b, and 100c for a vehicle may be used in a harsher environment (e.g., high current influence, high heat generation influence, high variability in vehicle operation, high variability in the vehicle external environment, and/or the like) and may cause more heat generation. Therefore, the adhesive member 150 of the power modules 100a, 100b, and 100c for a vehicle should (e.g., may be required to) have higher reliability.

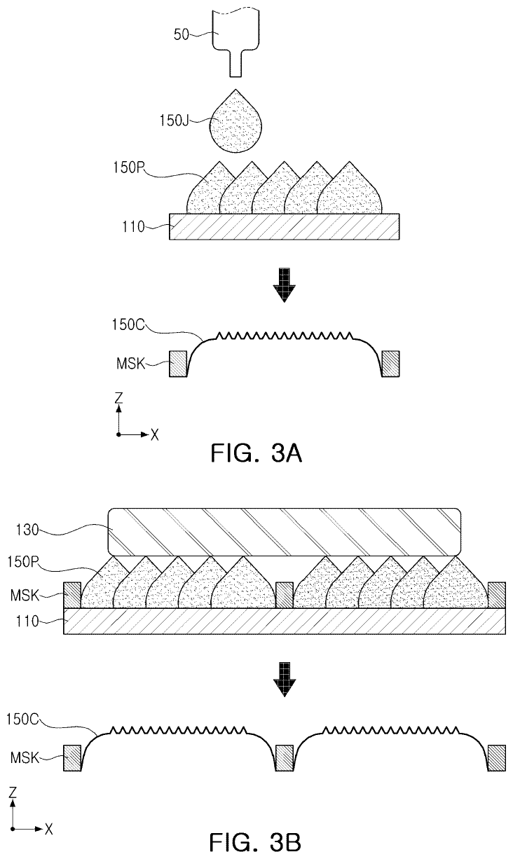

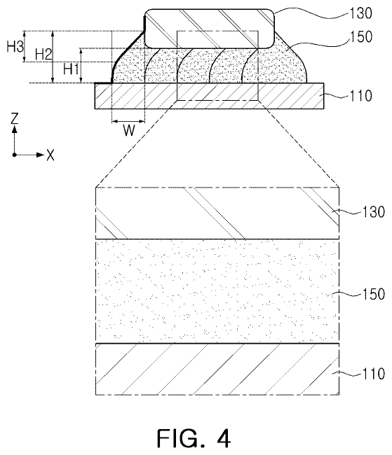

FIG. 3A is a side view illustrating applying an adhesive material of a power module for a vehicle in a jetting manner according to an embodiment of the present disclosure, FIG. 3B is a side view illustrating applying an adhesive material to a portion of a component of a power module for a vehicle according to an embodiment of the present disclosure, and FIG. 4 is a side view illustrating a shape of an adhesive member of a power module for a vehicle according to an embodiment of the present disclosure.

Referring to FIGS. 3A and 3B, an adhesive material 150J may be applied to the first circuit board 110 in a jetting manner and may be bonded between the first circuit board 110 and the switching component 130. Depending on the design, the first circuit board 110, an application target of the adhesive material 150J, may be redisposed with the second circuit board 120 or the switching component 130 of FIG. 1A.

The jetting method may be a method of applying a plurality of point-shaped adhesive materials 150J to different locations and connecting the points to each other. For example, since a nozzle 50 may apply the adhesive material 150J in a jetting manner, a diameter of the adhesive material 150J may be determined by a diameter of an application hole of the nozzle 50. The spacing between the different locations may be determined by the diameter of the adhesive material 150J and may be set (e.g., narrow enough) to connect adjacent points.

Since the adhesive material 150J is in a point shape, an edge (e.g., boundary) of the applied adhesive material 150P may be slanted with respect to a facing surface of the application target (e.g., the first circuit board 110) or the adhesion target (e.g., the switching component 130). Meanwhile, the surface of the applied adhesive material 150P facing the application target (e.g., the first circuit board 110) or the adhesion target (e.g., the switching component 130) may be substantially flattened by the connection of (e.g., between) a plurality of points of the adhesive material 150J.

Therefore, referring to FIG. 4, the boundary of the edge portion is thinner than the center portion in the adhesive member 150 and may be slanted with respect to the adhesion surface of the center portion of the adhesive member 150. For example, the boundary of the edge portion may be more curved than the adhesion surface of the center portion of the adhesive member 150. The curved shape may include a round shape, a concave shape, and/or a convex shape. The curvedness (e.g., curvature) of the boundary may be measured by a value (e.g., numerator/denominator) obtained by dividing a distance (e.g., numerator) between the center of a straight line connecting two end points of the boundary and the center of the boundary by a length (e.g., denominator) of the straight line.

Stress due to heat generation of the power modules 100a, 100b, and 100c for a vehicle or stress due to an external environment may impact the adhesive member 150 through the edge boundary of the adhesive member 150. Since the edge boundary of the adhesive member 150 is slanted or curved, the influence of the stress due to heat generation or stress due to an external environment on the adhesive member 150 may be reduced. Accordingly, the adhesive member 150 may be more robust to heat generation of the power modules 100a, 100b, and 100c for a vehicle or harsh environments (e.g., high current influence, high heat generation influence, high variability in vehicle operation, high variability in the external environment of the vehicle, and/or the like) and may have greater (e.g., higher) reliability.

Since the adhesive member 150 may be formed in a jetting manner, the formation of edges that are (e.g., locally) thickened, such as a dog ear shape, may be prevented, and the formation of edges that are lifted, such as a burr shape, may be prevented. For example, the dog ear shape may occur by a screen-printing method, a method different from the jetting method, and the burr shape may occur by a film attachment method, a method different from the jetting method. The edge boundary of the adhesive member formed by the screen-printing method and the film attachment method does not become obliquely thinner than the center portion.

Compared to the other methods (e.g., screen-printing method or film attachment method), the jetting method may reduce wasting adhesive material 150J due to an error in the application point of the adhesive material 150J. For example, since the screen-printing method and the film attachment method may be affected by positional errors on a surface-by-surface basis. Therefore, the waste of adhesive material due to positional errors in the screen-printing method and the film attachment method may be relatively large, and the dog ear shape and the burr shape may also be caused by the waste of adhesive material due to positional errors. Point-by-point jetting method may reduce positional errors.

For example, when the adhesive material 150J is applied, a position indicator MSK (shown in at least FIGS. 3A and 3B) may be temporarily disposed on the first circuit board 110 to improve the accuracy of the application position, but the position indicator MSK may be omitted depending on the design.

For example, referring to FIG. 4, the edge portion of the adhesive member 150 may not overlap the switching component 130 in a direction (e.g., the Z-direction) in which the center of the adhesive member 150 and the center of the switching component 130 face each other. For example, a maximum width W of the edge portion of the adhesive member 150 not overlapping the switching component 130 may be greater than 0 μm and less than or equal to 50 μm. An (e.g., appropriate) range (e.g., 50 μm or less) of the maximum width W may be determined by an (e.g., appropriate) gap H1 between the first circuit board 110 and the switching component 130, an (e.g., appropriate) maximum thickness H2 of the adhesive member 150, and an (e.g., appropriate) height H3 of the slanted boundary.

Referring back to FIG. 1A, the power module 100a for a vehicle according to an embodiment of the present disclosure may further include a spacer 140 disposed on the switching component 130, the switching component 130 may be disposed between the first circuit board 110 and the spacer 140, and the spacer 140 may be disposed between the second circuit board 120 and the switching component 130.

The spacer 140 may be disposed on the power module 100a for a vehicle to maintain an (e.g., appropriate) gap between the first circuit board 110 and the second circuit board 120 when the (e.g., appropriate) gap is greater than the thickness of the switching component 130. For example, the spacer 140 may include a metal material having high thermal conductivity (e.g., copper and/or molybdenum) to provide a heat dissipation path for the switching component 130. For example, the spacer 140 may include a via to provide an electrical connection path between the switching component 130 and the second circuit board 120.

The adhesive member 150 may include a first adhesive member 151 bonded between the first circuit board 110 and the switching component 130, a second adhesive member 152 bonded between the switching component 130 and the spacer 140, and a third adhesive member 153 bonded between the spacer 140 and the second circuit board 120. In at least one of the first adhesive member 151, the second adhesive member 152, and/or the third adhesive member 153, the boundary of the edge portion (e.g., thinner than the center portion) may be slanted with respect to the adhesion surface of the center portion. For example, each of the first adhesive member 151, the second adhesive member 152, and the third adhesive member 153 may be formed in a jetting manner.

For example, the power module 100a for a vehicle may include an encapsulant 160 encapsulating the switching component 130 and the spacer 140 and directly contacting the boundary of an edge portion of at least one of the first adhesive member 151, the second adhesive member 152, and the third adhesive member 153. The encapsulant 160 may protect the power module 100a for a vehicle to reduce harsh environmental influences (e.g., impact, inflow of foreign substances) from the outside of the power module 100a for a vehicle to the power module 100a for a vehicle. For example, the encapsulant 160 may include a molding material, such as epoxy molding compound (EMC), or the encapsulant 160 may include a silicone gel, but is not limited thereto.

Referring to FIG. 1B, the power module 100b for a vehicle according to an embodiment of the present disclosure may not include the second circuit board 120 and the spacer 140 of FIG. 1A, and may not include the second adhesive member 152 and the third adhesive member 153 of FIG. 1A. For example, the power module 100b for a vehicle may include a cooling member 170 disposed on an upper surface of the switching component 130.

For example, the cooling member 170 may have a shape (e.g., a plurality of protrusions are formed) efficient in increasing a surface area relative to the volume. For example, the cooling member 170 may be implemented with a material having high durability and/or thermal conductivity (e.g., a metal material, gold (Au), silver (Ag), copper (Cu), iron (Fe), graphite, graphene, and/or the like) or may be implemented with a material (e.g., polymer, ceramic, and/or the like) resistant to harsh external environments.

Referring to FIGS. 1C and 1D, the switching component 130 of the power module 100c for a vehicle according to an embodiment of the present disclosure may include a plurality of switching components 136, 137, 138, and 139 having different thicknesses. A (e.g., first) portion and another (e.g., second) portion of the second adhesive member 152 may be spaced apart from each other and bonded to each of the plurality of switching components 136, 137, 138, and 139.

Since the plurality of switching components 136, 137, 138, and 139 have different thicknesses, unlike an upper surface B1 of the first circuit board 110, a surface B2 connecting a plurality of upper surfaces of the plurality of switching components 136, 137, 138, and 139 may have a step. Since the jetting method may not be substantially affected by the operation of the surface B2, it may be an (e.g., efficient) method for forming the second adhesive member 152 on the surface B2 having the step.

For example, the plurality of switching components 136, 137, 138, and 139 may include a combination of at least two of an IGBT switching component, a silicon carbide (SiC) MOSFET switching component, and a Si MOSFET switching component and may have different thicknesses.

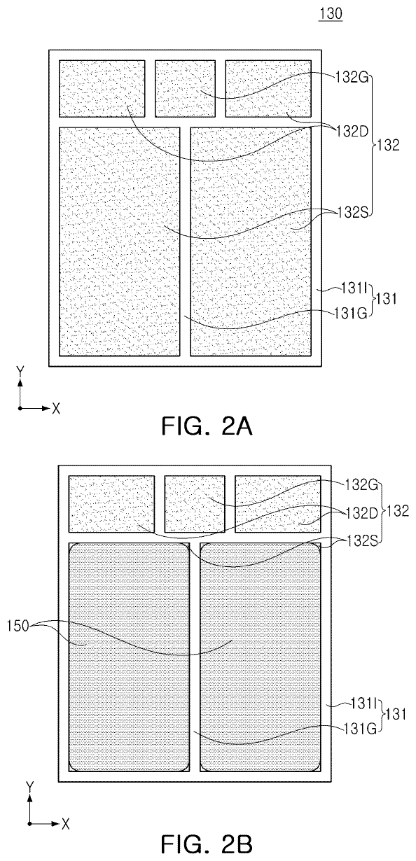

FIG. 2A is a plan view illustrating a switching component of a power module for a vehicle according to an embodiment of the present disclosure, and FIG. 2B is a plan view illustrating a structure in which an adhesive material is (e.g., intensively) applied to a portion of a switching component of a power module for a vehicle according to an embodiment of the present disclosure.

Referring to FIG. 2A, the switching component 130 may have a plurality of active regions 132 and a gate runner region 131G between the plurality of active regions 132. When the switching component 130 is a MOSFET, the plurality of active regions 132 may include a plurality of source regions 132S, a plurality of drain regions 132D, and a gate region 132G. When the switching component 130 is an IGBT, the source and drain may be replaced with an emitter and a collector.

In upper and lower surfaces of the switching component 130, regions other than the plurality of active regions 132 may be configured as an insulating region 131, and the insulating region 131 may include the gate runner region 131G between the plurality of source regions 132S. The gate runner region 131G may be a region extending in one direction (e.g., in a-Y direction) from the gate region 132G.

The adhesive member 150 may be bonded to the switching component 130 to overlap at least a portion of the plurality of active regions 132 (e.g., the plurality of source regions 132S). Accordingly, the adhesive member 150 may (e.g., efficiently) form a heat generation path and/or an electrical connection path of the switching component 130.

The gate runner region 131G may have relatively weak durability or may be prone to stress concentration, and the bonding of the adhesive member 150 may affect the stress. The adhesive member 150 may not be disposed in the gate runner region 131G, which may reduce the influence of the stress and improve the reliability of the gate runner region 131G. That is, a plurality of portions of the adhesive member 150 disposed in the plurality of active regions 132 may be spaced apart from each other with the gate runner region 131G therebetween. In addition, since the adhesive member 150 may include a metal material, an electrical short may also be prevented as the adhesive member 150 is not disposed in the gate runner region 131G. When the adhesive member 150 is formed in a jetting manner, the positional accuracy of the adhesive member 150 may be further improved.

Each of a plurality of corners of the adhesion surface of the adhesive member 150 may have a more chamfered shape than each of the plurality of corners of the plurality of active regions 132. The boundary facing the gate runner region 131G in the adhesive member 150 may be slanted with respect to the adhesion surface bonded to the plurality of active regions 132 in the adhesive member 150. For example, the chamfered shape and the slanted boundary may each be implemented as the adhesive member 150 is formed according to a jetting method, but is not limited thereto.

For example, the form in which the adhesive member 150 does not overlap the gate runner region 131G may be implemented as the adhesive material 150P of FIG. 3B is not applied to the center of the switching component 130, but is not limited thereto.

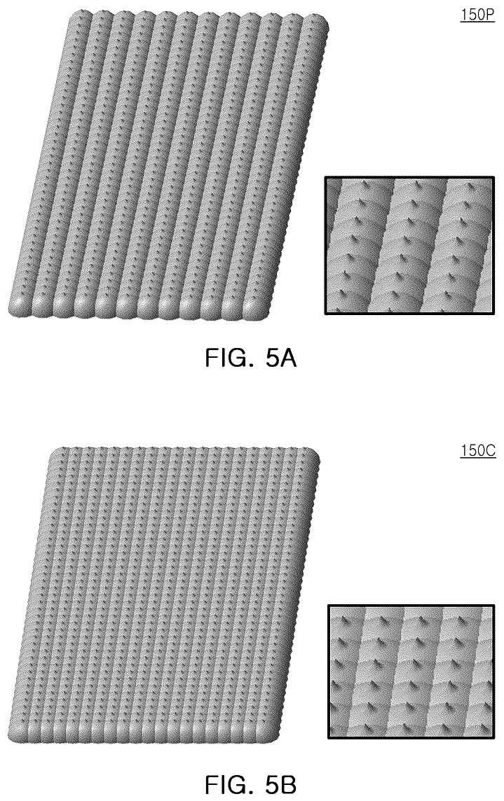

FIG. 5A is a perspective view illustrating an applied adhesive material of a power module for a vehicle before being flattened according to an embodiment of the present disclosure, and FIG. 5B is a perspective view illustrating a flattened adhesive material of a power module for a vehicle after being applied according to an embodiment of the present disclosure.

FIG. 5A may correspond to the upper portion of FIG. 3A and the upper portion of FIG. 5A, and the adhesion surface of the applied adhesive material 150P may be uneven and may include a plurality of protrusions. The applied adhesive material 150P may change into an adhesive material 150C of FIG. 5B through flattening and/or curing. Flattening and/or curing may cause particle rearrangement of the applied adhesive material 150P.

FIG. 5B may correspond to the lower portion of FIG. 3A and the lower portion of FIG. 3B. The adhesion surface of the center portion of the adhesive material 150C may become flatter (e.g., micro-protrusions may remain). The adhesive material 150C may not have a significant influence on the shape of the edge boundary of the adhesive material 150C while being bonded between the first circuit board 110 and the switching component 130.

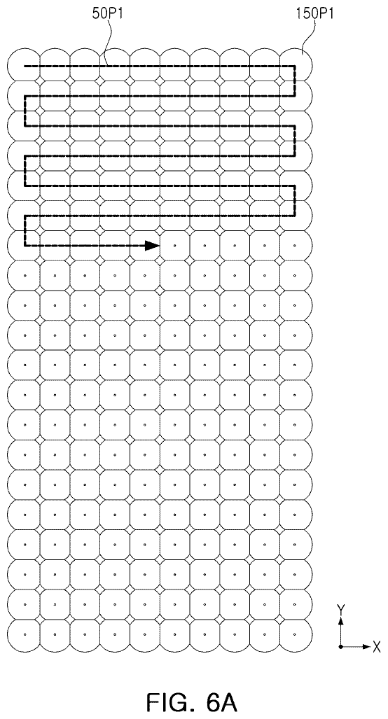

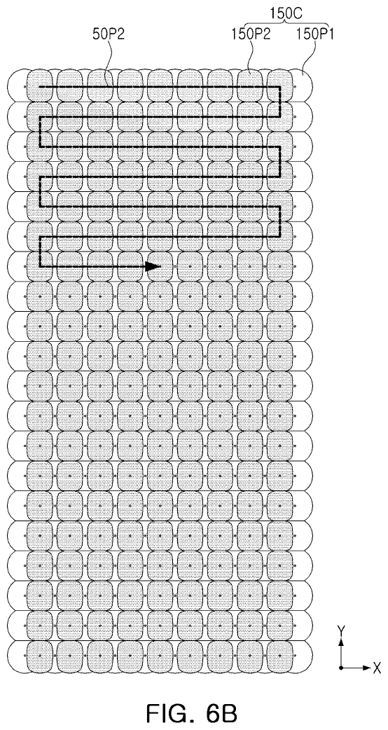

FIG. 6A is a plan view illustrating applying a portion of an adhesive material along a first application path in a jetting manner in a method of a manufacturing a power module for a vehicle according to an embodiment of the present disclosure, and FIG. 6B is a plan view illustrating applying another portion of the adhesive material along a second application path in a jetting manner in a method of a manufacturing a power module for a vehicle according to an embodiment of the present disclosure.

Referring to FIG. 6A, the nozzle (e.g., 50 of FIG. 3A) may form a first applied adhesive material 150P1 by applying a portion of an adhesive material along a first application path 50P1 of a predetermined application region of at least one of the circuit board and the switching component in a jetting manner.

Referring to FIG. 6B, the nozzle (e.g., 50 of FIG. 3A) may form a second applied adhesive material 150P2 on the first applied adhesive material 150P1 by applying another portion of the adhesive material along a second application path 50P2 of the predetermined application region in a jetting manner.

In the predetermined application region, at least a portion of the second application path 50P2 may not overlap the first application path 50P1. Accordingly, the second applied adhesive material 150P2 may be more concentratedly disposed on concave portions of the first applied adhesive material 150P1. Accordingly, the adhesion surface of the adhesive material 150C according to the combination of the first applied adhesive material 150P1 and the second applied adhesive material 150P2 may become flatter (e.g., micro-protrusions may remain). For example, the coordinates (e.g., X coordinate and/or Y coordinate) of a point at which the direction of the second application path 50P2 turns may not overlap the coordinates of a point at which the direction of the first application path 50P1 turns.

As particles of the first applied adhesive material 150P1 become larger, the resolution of the jetting-type application may become lower, and the efficiency of the jetting-type application (e.g., costs of implementing nozzle control) may be improved (or the time (e.g., required) may be shortened). The flatness of the upper surface of the first applied adhesive material 150P1 may become lower as the particles of the first applied adhesive material 150P1 become larger, but the second applied adhesive material 150P2 may offset the decrease in the flatness. Therefore, the formation of the adhesive material 150C according to the combination of the first applied adhesive material 150P1 and the second applied adhesive material 150P2 may be a method of improving both the efficiency of the jetting-type application and the flatness of the adhesion surface.

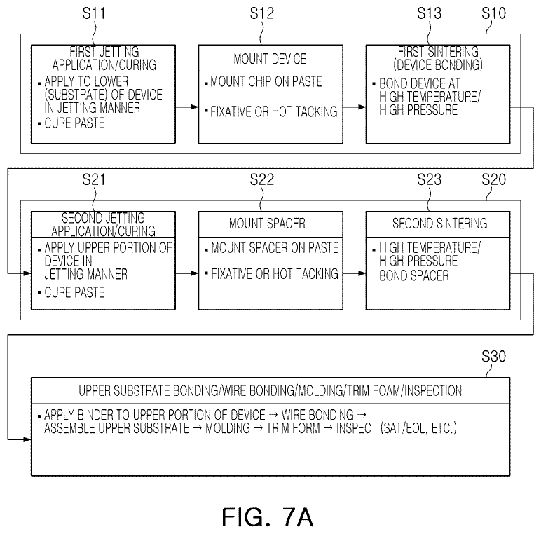

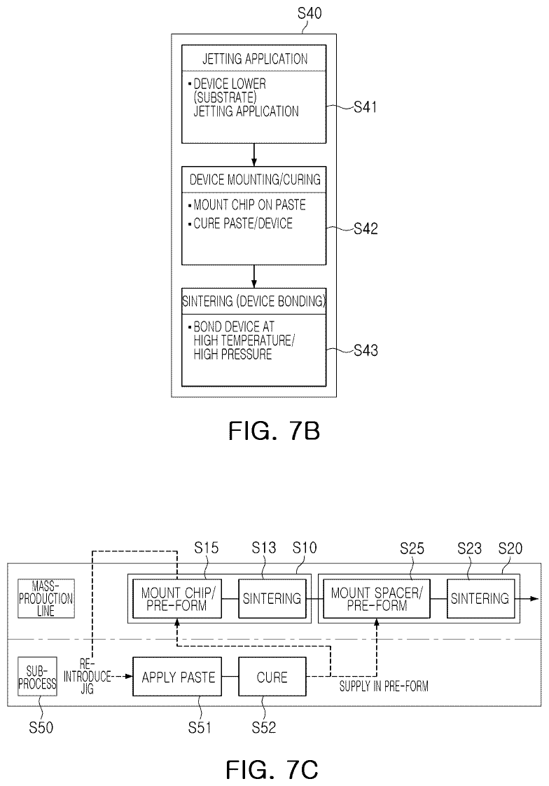

FIG. 7A is a flowchart illustrating a method for manufacturing a power module for a vehicle according to an embodiment of the present disclosure, FIG. 7B is a flowchart illustrating a change in a curing time of a method for manufacturing a power module for a vehicle according to an embodiment of the present disclosure, and FIG. 7C is a flowchart illustrating a preform process of an adhesive material in a method for manufacturing a power module for a vehicle according to an embodiment of the present disclosure.

Referring to FIGS. 1A, 3A, and 7A, a method for manufacturing a power module for a vehicle according to an embodiment of the present disclosure may include operations S11 and S21 of applying the adhesive material 150J to at least one of the circuit board (e.g., the first circuit board 110 and/or the second circuit board 120) and the switching component 130 in a jetting manner and may include operations S13 and S23 of forming the adhesive member 150 bonded to at least one of the circuit board (e.g., the first circuit board 110 and/or the second circuit board 120) and the switching component 130 by sintering the applied adhesive material 150P. For example, the sintering may be a process of sintering at a high temperature (e.g., 120 degrees Celsius or higher) and a high pressure (e.g., 10 MPa).

Accordingly, the waste of the adhesive material 150J due to an error in an application point of the adhesive material 150J may be reduced, and formation of an edge in which the thickness locally becomes thicker, such as a dog ear shape, in the adhesive member 150 may be prevented, and formation of an edge that is lifted, such as a burr shape, in the adhesive member 150 may be prevented.

For example, the operation of forming the adhesive member may include forming the first adhesive member 151 bonded between the first circuit board 110 and the switching component 130 (S13) and forming the second adhesive member 152 bonded between the switching component 130 and the spacer 140 (S23), and the applying operation may include applying a first adhesive material (e.g., paste), the base of the first adhesive member 151, in a jetting manner (S11), and applying a second adhesive material (e.g., paste), the base of the second adhesive member 152, in a jetting manner (S21).

For example, the applying operation may include hot tacking the switching component on the first circuit board 110 to mount the switching component (device) on the first circuit board 110 (S12). For example, the applying operation may include hot tacking (S22) the spacer 140 on the switching component 130 to mount the spacer 140 on the switching component (e.g., device). For example, the hot tacking may be performed at a temperature and pressure lower than the temperature and pressure of sintering, and a fixative for hot tacking may be used, but is not limited thereto.

For example, the method for manufacturing a power module for a vehicle may further include a post-process (S30) of a first bonding operation (S10) between the switching component 130 and the first circuit board 110 and a second bonding operation (S20) between the spacer 140 and the switching component 130. For example, the post-process (S30) may include bonding the second circuit board (upper substrate) to the spacer 140, forming wire bonding on the switching component 130, forming a molding (forming an encapsulant) between the first and second circuit boards 110 and 120, a trim form operation of trimming the outer shape of the power module for a vehicle, and inspecting the power module for a vehicle (e.g., scanning acoustic tomography (SAT) inspection, end of line (EOL) inspection, automated optical inspection (AOI)).

For example, each of the first bonding operation (S10) and the second bonding operation (S20) may include applying an adhesive material along the first and second application paths illustrated in FIGS. 6A and 6B in a jetting manner, respectively. That is, the applying operations (S11 and S21) may include applying a portion of the first adhesive material along a 1 -1 application path of a predetermined first application region in a jetting manner, applying another portion of the first adhesive material along a 1-2 application path of the predetermined first application region in a jetting manner, applying a portion of the second adhesive material along a 2-1 application path of a predetermined second application region in a jetting manner, and applying another portion of the second adhesive material along a 2 -2 application path of the predetermined second application region in a jetting manner, and within the predetermined first application region, at least a portion of the 1-2 application path may not overlap the 1 -1 application path, and within the predetermined second application region, at least a portion of the 2 -2 application path may not overlap the 2-1 application path.

For example, the first bonding operation (S10) may include forming a structure in which the adhesive member 150 illustrated in FIGS. 2A and 2B does not overlap the gate runner region 131G. That is, the applying operations (S11 and S21) may include applying an adhesive material to a predetermined application region in a jetting manner, and the predetermined application region may overlap each of the plurality of active regions (132 of FIG. 2B) and may not overlap the gate runner region (131G of FIG. 2B).

For example, the second bonding operation (S20) may include forming the second adhesive member 152 on the plurality of switching components 136, 137, 138, and 139 illustrated in FIG. 1C. That is, a predetermined application region may overlap each of the plurality of switching components (136, 137, 138, and 139 of FIG. 1C) and may not overlap regions between the plurality of switching components (136, 137, 138, and 139 of FIG. 1C).

For example, the applying operation may include curing the applied first adhesive material before sintering (S11 of FIG. 7A and S42 of FIG. 7B) and curing the applied second adhesive material before sintering (S22 of FIG. 7A and S42 of FIG. 7B). Curing may be a process for removing internal additives of the applied adhesive material. Sintering may improve the adhesiveness of the adhesive material immediately after curing.

For example, as illustrated in FIG. 7A, the curing process performed before hot tacking (S12 and S22) may be a dry process. For example, as illustrated in FIG. 7B, a curing process performed after hot tacking (S42) may be a wet process. Referring to FIG. 7B, bonding (S40) at least one of the circuit board, the switching component 130, and the spacer 140 may include applying (S41) in a jetting manner, hot tacking (S42), and sintering (S43).

Referring to FIG. 7C, a sub-process (S50) may be separated from a mass-production line and may include applying (S51) and curing (S52) an adhesive material (e.g., paste). A pre-form of the adhesive material formed by the sub-process (S50) may be provided to each of a switching component (e.g., chip) hot tacking process (S15) and a spacer hot tacking process (S25) of the mass-production line. For example, a jig may transfer the pre-form of the adhesive material from the sub-process (S50) to the mass-production line, and then may be re-introduced to the sub-process (S50).

The power module for a vehicle and the method for manufacturing a power module for a vehicle according to an embodiment of the present disclosure may improve the bonding reliability of the switching components and/or circuit boards of the power module for a vehicle and may have improved resistance to heat generation or harsh environments (e.g., high current influence, high heat generation influence, high variability in vehicle operation, high variability in the vehicle external environment, and/or the like).

For example, the power module for a vehicle and the method for manufacturing a power module for a vehicle according to an embodiment of the present disclosure may have a structure provided by a controlled application of the amount and/or location of the adhesive material, may prevent the occurrence of a dog ear shape or a burr shape at the edge of the adhesive member, and may reduce the waste of the adhesive material.

While embodiments have been shown and described above, it will be apparent to those skilled in the art that modifications and variations could be made without departing from the scope of the present disclosure as provided in the claims.

What is claimed is:

1. A power module for a vehicle, the power module comprising:
a circuit board;
a switching component disposed on the circuit board; and
an adhesive member bonded to at least one of the circuit board or the switching component,
wherein a boundary of an edge portion is slanted with respect to an adhesion surface of a center portion of the adhesive member.

2. The power module of claim 1, wherein the boundary of the edge portion is thinner than the center portion of the adhesive member and is more curved than the adhesion surface of the center portion of the adhesive member.

3. The power module of claim 1, wherein the adhesive member includes a metal material and is configured to be bonded to at least one of the circuit board or the switching component by sintering.

4. The power module of claim 1, further comprising:
a spacer provided on the switching component,
wherein the circuit board includes a first circuit board and a second circuit board,
the switching component is provided between the first circuit board and the spacer, and
the spacer is provided between the second circuit board and the switching component.

5. The power module of claim 4, wherein
the adhesive member includes:
a first adhesive member bonded between the first circuit board and the switching component;
a second adhesive member bonded between the switching component and the spacer; and
a third adhesive member bonded between the spacer and the second circuit board; and,
in at least one of the first adhesive member, the second adhesive member, or the third adhesive member, a boundary of an edge portion is slanted with respect to an adhesion surface of the center portion.

6. The power module of claim 5, further comprising an encapsulant encapsulating the switching component and the spacer and contacting the boundary of the edge portion of at least one of the first adhesive member, the second adhesive member, or the third adhesive member.

7. The power module of claim 1, wherein the adhesive member includes a first adhesive member bonded to the switching component, and an edge portion of the first adhesive member does not overlap the switching component in a direction in which a center of the first adhesive member and a center of the switching component face each other.

8. The power module of claim 7, wherein a maximum width of the edge portion of the first adhesive member not overlapping the switching component is greater than 0 μm and less than or equal to 50 μm.

9. The power module of claim 1, wherein
the adhesive member includes a first adhesive member bonded to the switching component,
the switching component includes a plurality of active regions and a gate runner region between the plurality of active regions, and
the first adhesive member is bonded to each of the plurality of active regions and is spaced apart from the gate runner region.

10. The power module of claim 9, wherein the first adhesive member includes an adhesion surface including a plurality of corners, each of the plurality of corners of the adhesion surface of the first adhesive member has a chamfered shape, the chamfered shape is greater than a shape of each of a plurality of corners of the plurality of active regions.

11. The power module of claim 9, wherein a boundary in the first adhesive member facing the gate runner region is slanted with respect to an adhesion surface of the first adhesive member bonded to the plurality of active regions.

12. The power module of claim 1, wherein the adhesive member includes:
a first adhesive member bonded to a first surface of the switching component; and
a second adhesive member bonded to a second surface of the switching component,
the switching component includes a plurality of switching components having different thicknesses, and
a first portion and a second portion of the second adhesive member are spaced apart and respectively bonded to the plurality of switching components.

13. A method for manufacturing a power module for a vehicle, the method comprising:
applying an adhesive material to at least one of a circuit board or a switching component in a jetting manner; and
sintering the applied adhesive material to form an adhesive member bonded to at least one of the circuit board or the switching component.

14. The method of claim 13, wherein
the circuit board includes a first circuit board and a second circuit board, and wherein
forming the adhesive member includes forming a first adhesive member bonded between the first circuit board and the switching component and forming a second adhesive member bonded between the switching component and a spacer, and
wherein applying the adhesive material includes applying a first adhesive material in a jetting manner and applying a second adhesive material in a jetting manner, and
wherein the first adhesive material is a base of the first adhesive member, and the second adhesive material is a base of the second adhesive member.

15. The method of claim 14, wherein applying the adhesive material includes curing the applied first adhesive material before sintering, and curing the applied second adhesive material before sintering.

16. The method of claim 14, wherein
applying the adhesive material includes:
applying a portion of the first adhesive material along a 1 -1 application path of a predetermined first application region of at least one of the circuit board or the switching component in a jetting manner;
applying another portion of the first adhesive material along a 1-2 application path of the predetermined first application region in a jetting manner;
applying a portion of the second adhesive material along a 2-1 application path of a predetermined second application region of at least one of the switching component or the spacer; and
applying another portion of the second adhesive material along a 2 -2 application path of the predetermined second application region in a jetting manner.

17. The method of claim 16, wherein
at least a portion of the 1-2 application path does not overlap the 1 -1 application path within the predetermined first application region, and
at least a portion of the 2 -2 application path does not overlap the 2-1 application path within the predetermined second application region.

18. The method of claim 13, wherein
applying the adhesive material includes:
applying a portion of the adhesive material along a first application path of a predetermined application region of at least one of the circuit board or the switching component in a jetting manner; and
applying another portion of the adhesive material along a second application path of the predetermined application region in a jetting manner,
wherein, within the predetermined application region, at least a portion of the second application path does not overlap the first application path.

19. The method of claim 13, wherein
applying the adhesive material includes applying an adhesive material to a predetermined application region of at least one of the circuit board or the switching component in a jetting manner,
the switching component has a plurality of active regions and a gate runner region between the plurality of active regions, and
the predetermined application region overlaps each of the plurality of active regions and does not overlap the gate runner region.

20. The method of claim 13, wherein
applying the adhesive material includes applying an adhesive material to a predetermined application region of at least one of circuit board or the switching component in a jetting manner,
wherein the switching component includes a plurality of switching components having different thicknesses, and
the predetermined application region overlaps each of the plurality of switching components and does not overlap a region between the plurality of switching components.
